(19) United States
(12) Patent Application Publication
(10) Pub. No.: US 2010/0017154 A1
(43) Pub. Date: Jan. 21, 2010

(54) Battery Monitoring and Protecting Device

(76) Inventor: Yu-Ta Tu, Taipei (TW)

Correspondence Address: David Shung, P.O. Box 10557, Taipei, 100, TW

(21) Appl. No.: 12/503,226

(22) Filed: Jul. 15, 2009

(30) Foreign Application Priority Data
Jul. 21, 2008 (TW) 097127575

(51) Int. Cl. G01R 31/36

(52) U.S. Cl. 702/63

(57) ABSTRACT

A battery monitoring and protecting device is disclosed. The device includes a voltage detector, an analog-to-digital converter, a controller and a communication interface. Also, the device has an ID code, by which whether the device is actuated can be determined. The data stored in the device can be sent out to communicate with an external unit at next timing phase if the device is actuated. This can prevent from interference or collision with each other when multiple devices are connected in parallel or series.

### BACKGROUND OF THE INVENTION

1. Technical Field

The invention generally relates to batteries, particularly to devices for monitoring batteries.

2. Related Art

In this period of high price of petroleum, it is certain that petroleum fuel is replaced by electricity, especially for vehicles. The power output by a single battery is frequently limited, so it is usually necessary to connect multiple batteries in parallel or series to form a battery set with larger power. A malfunction of any single unit of the battery set tends to cause disablement of the battery set if without a monitoring device.

Battery monitoring is not only for a single battery but for a battery set formed by multiple batteries. However, existing battery monitoring technique for a battery set is still deficient.

### SUMMARY OF THE INVENTION

A primary object of the invention is to provide a battery monitoring and protecting device which can monitor the status of battery and prevent from interference or collision when connecting multiple batteries in parallel or series.

To accomplish the above object, the battery monitoring and protecting device includes:

a voltage detector for detecting a voltage value of a battery;

an analog-to-digital converter for converting the voltage value into a digital value;

a controller for processing the digital value;

a communication interface for sending the processed digital value out; and

an ID code;

wherein the controller, according to the ID code, determines whether the battery monitoring and protecting device is actuated, and data stored in the battery monitoring and protecting device can be sent out to communicate with an external unit at next timing phase if the battery monitoring and protecting device is actuated.

### BRIEF DESCRIPTION OF THE DRAWINGS

FIG. 1 is a systematic block diagram of the invention; and

FIG. 2 shows a practical embodiment of the invention applied in multiple batteries in series or parallel.

### DETAILED DESCRIPTION OF THE INVENTION

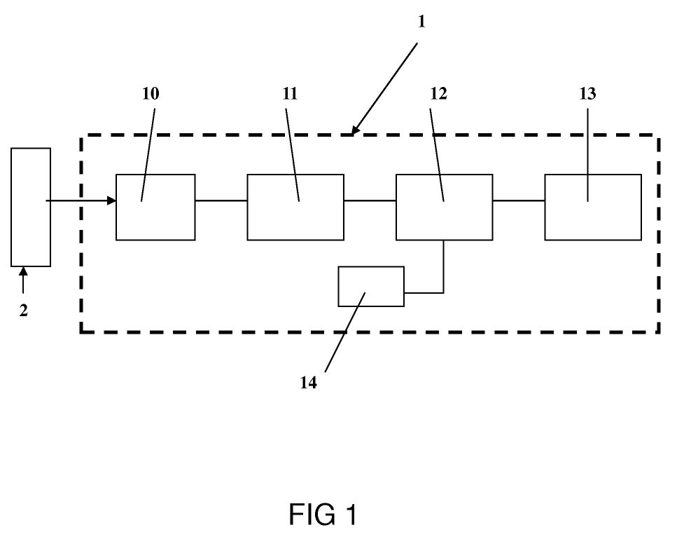

Referring to FIG. 1, the battery monitoring and protecting device independently connects to a battery unit 2 to be protected. The device includes:

a voltage detector 10, electrically connecting to the battery unit 2, and detecting a voltage value of the battery unit 2;

an analog-to-digital converter 11, electrically connecting to the voltage detector 10, and converting the voltage value into a digital value;

a controller 12, electrically connecting to the analog-to-digital converter 11, and processing the digital value;

a communication interface 13, electrically connecting to the controller 12, and sending the processed digital value out; and

an ID code 14;

wherein the controller 12, according to the ID code 14, determines whether the battery monitoring and protecting device is actuated, and data stored in the battery monitoring and protecting device can be sent out to communicate with an external unit at next timing phase if the battery monitoring and protecting device is actuated.

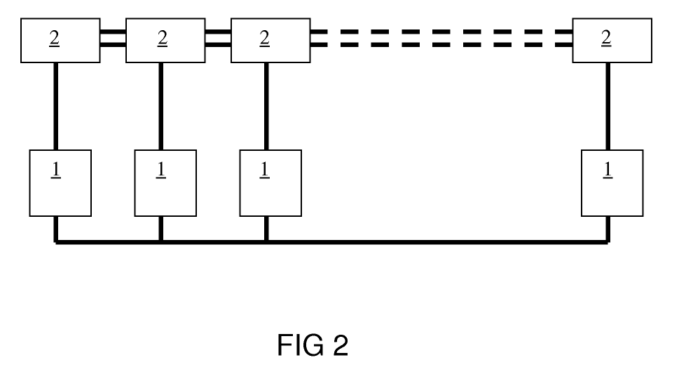

Referring to FIG. 2, when plural battery units are connected to form a battery set, the controller 12 of each independent battery monitoring and protecting device, according to the respective ID code 14, determines whether the battery monitoring and protecting device is actuated, and data stored in the battery monitoring and protecting device can be sent out to communicate with an external unit at next timing phase if the battery monitoring and protecting device is actuated. This can prevent from interference or collision with each other when multiple devices are connected in parallel or series. Thus, the stability and safety of the battery can be ensured.

It will be appreciated by persons skilled in the art that the above embodiment has been described by way of example only and not in any limitative sense, and that various alterations and modifications are possible without departure from the scope of the invention as defined by the appended claims.

What is claimed is:

1. A battery monitoring and protecting device comprising:
a voltage detector, electrically connecting to a battery, and detecting a voltage value of the battery;
an analog-to-digital converter, electrically connecting to the voltage detector, and converting the voltage value into a digital value;
a controller, electrically connecting to the analog-to-digital converter, and processing the digital value;
a communication interface, electrically connecting to the controller, and sending the processed digital value out; and
an ID code;
wherein the controller, according to the ID code, determines whether the battery monitoring and protecting device is actuated, and data stored in the battery monitoring and protecting device can be sent out to communicate with an external unit at next timing phase if the battery monitoring and protecting device is actuated.
